(19) United States
(12) Patent Application Publication
(10) Pub. No.: US 2014/0159801 A1
(43) Pub. Date: Jun. 12, 2014

(54) Performance Adaptive Voltage Scaling with Performance Tracking Sensor

(71) Applicant: Texas Instruments Incorporated, Dallas, TX (US)

(72) Inventors: Jose Luis Flores, Richardson, TX (US); Anthony Martin Hill, Dallas, TX (US); Francisco Adolfo Cano, Sugar Land, TX (US)

(21) Appl. No.: 14/103,433

(22) Filed: Dec. 11, 2013

Related U.S. Application Data
(60) Provisional application No. 61/736,229, filed on Dec. 12, 2012.

(51) Int. Cl. H03K 3/012

(52) U.S. Cl. CPC H03K 3/012
USPC 327/513

(57) ABSTRACT

Power consumption is reduced by the use of a plurality of parameter reference targets, optimized for a subset of the complete temperature range. The prediction accuracy of the performance tracking sensor is optimized by using small segments of the operating temperature range.

### CLAIM OF PRIORITY

This application claims priority under 35 U.S.C. 119(e)(1) to Provisional Application No. 61/736,229 filed Dec. 12, 2012.

### TECHNICAL FIELD OF THE INVENTION

The technical field of this invention is adaptive voltage scaling.

### BACKGROUND OF THE INVENTION

Frequency and voltage scaling are common place in electronic processors. These devices are providing more and more functionality and demand the highest data processing efficiency. Adaptive Voltage Scaling (AVS) provides the lowest operation voltage for a given processing frequency by utilizing a closed loop approach. The AVS loop regulates processor performance by automatically adjusting the output voltage of the power supply to compensate for process and temperature variation in the processor. In addition, the AVS loop trims out power supply tolerance. When compared to open loop voltage scaling solutions like Dynamic Voltage Scaling (DVS), AVS uses up to 45% less energy.

Power savings is further optimized by partitioning the SoC design into several independent voltage domains. For example, the processor may have a core and a hardware accelerator that operate on different scaling voltage domains. The AVS enables control of multiple AVS domains, commonly needed in state-of-the-art SoC design.

The way to reduce energy consumption in a processor, is to not only to reduce the clock frequency as low as possible, but, more importantly, to reduce the core supply voltage to the minimum amount for a given clock frequency.

FIG. 1 illustrates the energy savings gained with voltage scaling where curve 101 is without AVS and curve 102 is with AVS enabled.

A simple approach to AVS is to generate a voltage vs. frequency table. These voltages are the minimum needed to maintain functionality over all parts and temperature.

While open loop AVS can yield a good amount of energy savings, it does not realize all the energy savings available. Alternately, a closed loop approach may also be used where the performance of the logic is measured to assist in deriving the minimum acceptable voltage for satisfactory operation.

Every operating frequency/voltage pair in a processor must be characterized such that over parts and temperature the operating voltage is high enough to meet timing criteria.

This characterized voltage must also include headroom for the power supply regulation error (typically 5 to 10%). Accounting for process, temperature, and power supply variation, the table based AVS is at best conservative, and requires characterization at all the operating frequencies.

### SUMMARY OF THE INVENTION

Adaptive voltage scaling performance tracking based sensors are usually characterized during manufacturing and that characterization will identify the best set of parameters, which we will call parameter-reference-targets.

The silicon die is characterized across all the temperature operation range and then a set of parameter-reference-targets are identified and used. That set of parameters have to have a large margin such that the silicon die is fully functional across the temperature range and that large margin results in the use of additional power.

The solution shown in this invention reduces and minimizes those margins by splitting the complete temperature range into several segments, for example 5 segments, and then identifies the optimum set of parameter-reference-targets for each segment rather than a single parameter set for the entire range. A precision temperature monitor is used to update the parameter-reference-targets of the sensor depending on the actual temperature measured in the die. The improvement in accuracy will result in a significant reduction of power consumption.

### BRIEF DESCRIPTION OF THE DRAWING

These and other aspects of this invention are illustrated in the drawing, in which:

FIG. 1 is a graph demonstrating the power savings attributable to adaptive voltage scaling;

FIG. 2 is a flow chart demonstrating one implementation of adaptive voltage scaling;

FIG. 3 shows a flow chart of a second implementation; and

FIG. 4 shows the manufacturing characterization process.

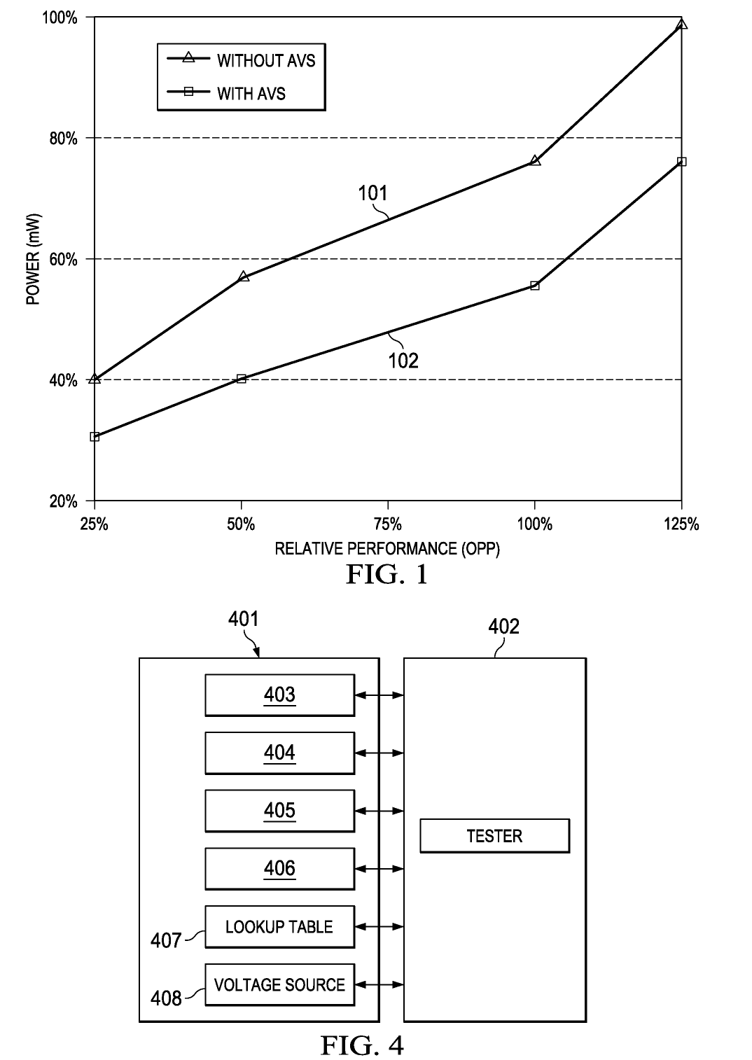

### DETAILED DESCRIPTION OF PREFERRED EMBODIMENTS

One of the most important technologies in this field is Texas Instrument's Adaptive Voltage Scaling (AVS) technology. Built around a scalable architecture, it offers the ability to adjust the power supply based on silicon strength, compensate for temperature, and remove system power supply margins.

The large SoCs currently integrate hundreds of millions of transistors, and operate with high power levels. Frequently the contribution of leakage power to the total power budget is significant. Additionally, many of the functional units of the SoC have fixed performance requirements, e.g., USB2.0 is always limited to 480 Mbits/s. Since the worst case leakage occurs with faster silicon, these devices traditionally exhibit the highest power.

Eliminating the performance headroom of these devices by lowering the supply voltage allows them to achieve lower power for the same function. The design goal of the Texas Instruments SmartReflex AVS technology was to effectively nullify the impact of leakage on customer's power budgets by lowering the voltage on faster silicon such that their total power was lower than the slowest silicon.

Temperature impact to performance varies with the operating voltage; at higher voltages, the logic gates slow as temperature increases, while at lower voltages, they speed up as temperature is increased. This is due to the opposing effects of threshold voltage variation and carrier mobility (threshold voltage decreases with increasing temperature, mobility decreases with increasing temperature). The margin required to guarantee device performance over the operating range can be relatively large; for this reason AVS allows for the automatic adjustment of the power supply in response to temperature changes of the silicon.

Power delivery includes many discrete components. Each of these has its own tolerances and variations, and is traditionally assumed to be at worst case when deriving system power delivery budgets. In practice, some or all of the components will not be at the worst case conditions, and in fact some are even mutually exclusive, e.g., while performance may be worst case at low temperature, the resistance of the copper interconnect lines is around 30% lower when compared to high temperature, hence the IR drop in the board and package routing is reduced at low temperature, thus offsetting the performance loss. The closed loop AVS system automatically corrects for these factors since it monitors logic performance at the end point of the power delivery network.

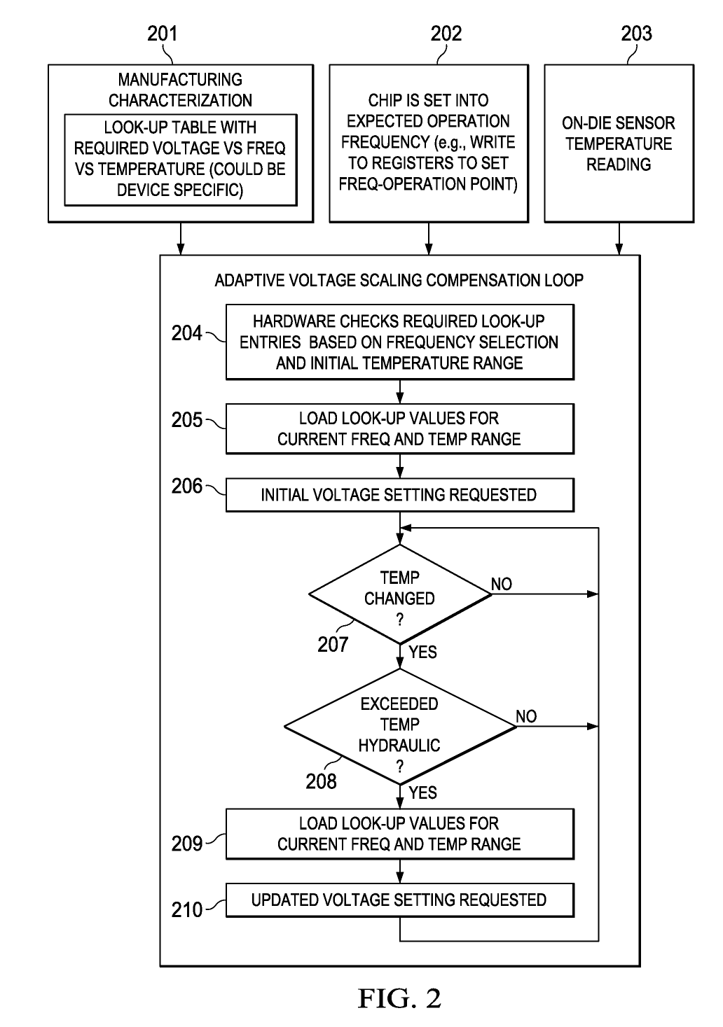

FIG. 2 shows one implementation of an adaptive voltage scaling system. Input 201 to the system is the manufacturing characterization data used to generate a lookup table with the required voltage, temperature and operating frequency values. Input 202 initializes the system with the expected operating frequency, and input(s) 203 is the output of the on chip temperature sensors.

Block 204 obtains the appropriate lookup table entries based on the initial expected frequency and the initial temperature range;

Block 205 loads the values from the lookup table based on the current frequency and temperature range;

Block 206 requests the initial operating voltage setting from the power supply based on the above data;

Comparator 207 determines whether the die temperature has changed from the previous value. If it has not, control returns to the input of comparator 207. If the temperature has changed, control flows to comparator 208.

Comparator 208 determines whether the temperature change detected by comparator 207 is larger than a preset hysteresis band. If it is not, control returns to the input of comparator 207. If the change exceeds the hysteresis band, block 209 gets the lookup table values for the current frequency and temperature range, and block 210 requests the updated voltage setting from the power supply. Control then returns to the input of comparator 207.

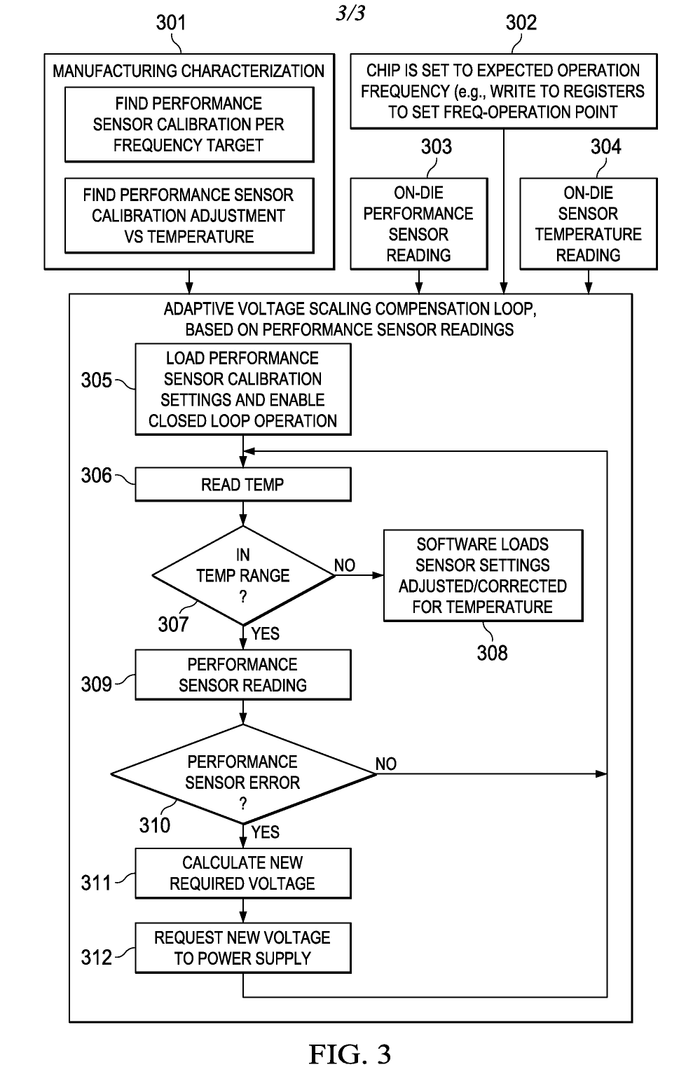

A second implementation is shown in FIG. 3 where blocks 301 through 304 generate the inputs to the adaptive voltage scaling system.

Block 301 generates the manufacturing characterization data. It determines the performance sensor calibration for the operating frequency targets, and also the performance sensor calibration adjustment dependant on temperature;

Block 302 sets the expected operating frequency. Block 303 provides the on die performance sensor reading, and Block 304 provides the on die temperature reading.

Block 305 loads the performance sensor calibration settings, and enables closed loop operation of the adaptive voltage scaling system.

The current die temperature is read in Block 306, and comparator 307 determines whether the reading is within the preset temperature range. If not, software Block 308 loads updated sensor settings corrected for the actual temperature. If the temperature is in range, Block 309 reads the performance sensor, and comparator 310 determines whether there is a performance sensor error. If there is none, control flow returns to Block 306. If there is an error, the required operating voltage to correct the error is calculated in Block 311, and Block 312 requests the updated voltage from the power supply. Control flow then returns to Block 306.

FIG. 4 shows the manufacturing characterization steps used in the invention, where 401 is the die under test and characterization, and 402 is the testing equipment. In the first implementation described above, tester 402 reads the temperature of die 401 using the output of temperature sensor 405 and/or temperature sensor 406. Lookup table 407 is generated by the tester using the temperature readings at a range of temperatures and the appropriate voltage for each temperature, and is then written into lookup table 407 on the die. During operation of the completed part, voltage source 408 is adjusted by the method of this invention based on the measured temperature and the contents of the lookup table.

In the second implementation described, one or more performance sensors 403-404 are also incorporated on the die. These performance sensors are typically implemented as free running ring oscillators, whose frequency is determined by the propagation delays of the gates in the oscillator. Since these delays are influenced by manufacturing and material tolerances, the resulting frequency will be representative of the “strength” of the particular die under test.

In this implementation, lookup table 407 is generated by the tester, and contains calibration data for performance sensor 403 and 404 based on a range of temperatures as measured by temperature sensor 405 and/or temperature sensor 406.

During operation of the completed part, performance sensor 403 and 404 are calibrated using calibration data contained in the lookup table according to the die temperature measured by sensors 405 and/or 406. Voltage source 408 is then adjusted by the method of this invention according to the performance measured by performance sensor 403 and/or 404.

What is claimed is:

1. A method of adaptive voltage scaling comprising the steps of:
calibrating performance sensor at a given operating frequency;
calibrating the performance sensor at a given die temperature;
repeating the calibration steps at a range of temperatures;
creating a lookup table containing performance sensor calibration data at the measured temperature ranges;
reading die temperature;
calibrating performance sensor with calibration data from the lookup table applicable to the measured temperature;
reading the performance sensor and adjusting the voltage source if there is a performance error.

2. The method of adaptive voltage scaling of claim 1 wherein:
one or more performance sensors are incorporated on the die.

3. The method of adaptive voltage scaling of claim 1 wherein:
one or more temperature sensors are incorporated on the die.

4. The method of adaptive voltage scaling of claim 1 wherein:
the lookup table is generated during initial manufacturing characterization of the die.

5. The method of adaptive voltage scaling of claim 1 wherein:
the operating voltage is periodically adjusted based upon changes in the output of a calibrated performance sensor.

6. The method of adaptive voltage scaling of claim 1 further comprising the steps of:
dividing the operating temperature range into a plurality ranges;
recalibrating the performance sensor with calibration data from the lookup table only when the measured die temperature changes from one of the temperature ranges into an other.
